(19) United States
(12) Patent Application Publication
(10) Pub. No.: US 2015/0049570 A1
(43) Pub. Date: Feb. 19, 2015

(54) MEMORY DEVICE, MEMORY SYSTEM INCLUDING THE SAME, OPERATING METHOD THEREOF

(71) Applicants: Sung-Hyun LEE, Gwangju-si (KR); Jun-Hee YOO, Ansan-si (KR); Dong-Soo KANG, Hwaseong-si (KR); Sua KIM, Seongnam-si (KR); Hak-Soo YU, Seongnam-si (KR); Jae-Youn YOUN, Seoul (KR); Hyo-Jin CHOI, Suwon-si (KR)

(72) Inventors: Sung-Hyun LEE, Gwangju-si (KR); Jun-Hee YOO, Ansan-si (KR); Dong-Soo KANG, Hwaseong-si (KR); Sua KIM, Seongnam-si (KR); Hak-Soo YU, Seongnam-si (KR); Jae-Youn YOUN, Seoul (KR); Hyo-Jin CHOI, Suwon-si (KR)

(21) Appl. No.: 14/450,537

(22) Filed: Aug. 4, 2014

(30) Foreign Application Priority Data
Aug. 16, 2013 (KR) 10-2013-0097278

(51) Int. Cl. G11C 8/08; G11C 8/10

(52) U.S. Cl. CPC G11C 8/08; G11C 8/10
USPC 365/230.03

(57) ABSTRACT

In one embodiment, the memory device includes at least one memory bank including first and second subbanks, and control logic configured to control storing data into the memory bank. The control logic is configured to activate the first subbank and to precharge the second subbank in response to a first activate command for the first subbank.

### CROSS-REFERENCE TO RELATED APPLICATION

This application claims priority from Korean Patent Application No. 10-2013-0097278 filed on Aug. 16, 2013 in the Korean Intellectual Property Office, and all the benefits accruing therefrom under 35 U.S.C. 119, the contents of which in its entirety are herein incorporated by reference.

### TECHNICAL FIELD

At least one example embodiment relates to a memory device, a memory system including the same, and/or an operating method thereof.

### BACKGROUND

A memory device is mainly classified into a volatile memory device and a nonvolatile memory device. The volatile memory device is a memory device in which stored data dissipates when a power supply is cut. The volatile memory device includes a static RAM (SRAM), a dynamic RAM (DRAM), a synchronous DRAM (SDRAM), and the like. The nonvolatile memory device is a memory device in which stored data is maintained even though a power supply is cut. The nonvolatile memory device includes a flash memory device, a read only memory (ROM), a programmable ROM (PROM), an electrically programmable ROM (EPROM), an electrically erasable and programmable ROM (EEPROM), or a resistive memory device (for example, a phase-change RAM (PRAM), a ferroelectric RAM (FRAM), or a resistive RAM (RRAM)).

### SUMMARY

At least one embodiment relates to a memory device.

In one embodiment, the memory device includes at least one memory bank including first and second subbanks, and control logic configured to control storing data into the memory bank. The control logic is configured to activate the first subbank and to precharge the second subbank in response to a first activate command for the first subbank.

In one embodiment, the control logic is configured to active the first subbank and not precharge the second subbank in response to a second activate command for the first subbank. In one embodiment, the control logic is configured to control a sense amplifier to precharge the second subbank.

In another embodiment the memory device includes, at least one memory bank which includes first and second subbanks, a row decoder configured to activate a row of one subbank which is selected from the first and second subbanks, in response to an ACT command, and first and second sense amplifiers configured to precharge the first and second subbanks, respectively, in response to a PRE command, wherein the second sense amplifier is configured to precharge the second subbank in response to an ACT command for activating a row of the first subbank.

At least one embodiment relates to a memory system.

In one embodiment the memory system includes, a memory device which stores data, and a memory controller configured to issue an ACT command and a PRE command to control the memory device. The memory device includes, at least one memory bank including first and second subbanks, a row decoder configured to activate a row of one subbank which is selected from the first and second subbanks, in response to the ACT command, and first and second sense amplifiers configured to precharge the first and second subbanks, respectively, in response to a PRE command. The second sense amplifier is configured to precharge the second subbank in response to a first ACT command for activating a row of the first subbank, and when a row of the second subbank is in an active status, the memory controller is configured to issue the first ACT command.

In another embodiment the memory system includes, a memory device configured to store data, and a memory controller configured to control the memory device. The memory device includes, at least one memory bank including a plurality of subbanks, a row decoder configured to activate a row of one subbank which is selected from the plurality of subbanks, and a plurality of sense amplifiers configured to precharge the plurality of subbanks, respectively. The memory controller is configured to issue an ACT command for activating a row of one subbank which is selected from the plurality of subbanks, and after issuing the ACT command, the memory controller is configured to not issue a PRE command but reissues an ACT command for activating the row of the one selected subbank.

At least one embodiment relates to a memory controller.

In one embodiment, the memory controller includes a processor configured to issue a first activate command to activate a first subbank in a bank of a memory device if a second subbank of the bank is active. The first activate command instructs the memory device to activate the first subbank and to precharge the second subbank.

In one embodiment, the memory controller includes a memory configured to store a respective status for each of the first and second subbanks. The status indicates whether the respective one of the first and second subbanks is active; and the processor is configured to generate the first activate command based on the statuses.

In one embodiment, the processor is configured to generate a second activate command to activate the first subbank if the second subbank is inactive. The second activate command instructs the memory device to activate the first subbank.

At least one embodiment relates to a method.

In one embodiment, the method includes activating, by control logic of a memory device, a first subbank of a bank in the memory device in response to a first activate command; and automatically precharging, by the control logic, a second subbank of the bank in response to the first activate command.

In another embodiment, the method includes determining, by control logic of a memory device, whether a received command is one of a first activate command and a second activate command. If the determining determines the received command is the first activate command, then the method further includes activating, by the control logic, a first subbank of a bank in the memory device in response to the first activate command; and automatically precharging, by the control logic, a second subbank of the bank in response to the first activate command.

In a further embodiment, the method includes, issuing, by a memory controller a first ACT command for activating a row of a first subbank of at least one memory bank of a memory device; activating the row of the first subbank in response to the first ACT command; issuing, by a memory controller, a second ACT command for activating a row of a second subbank which is different from the first subbank of the at least one memory bank; and precharging the first subbank in response to the second ACT command.

### BRIEF DESCRIPTION OF THE DRAWINGS

The above and other features and advantages of the example embodiments will become more apparent by describing the example embodiments in detail with reference to the attached drawings in which:

FIG. 1 is a block diagram illustrating a memory device according to an embodiment;

FIG. 2 is a circuit diagram illustrating subbanks of FIG. 1 in detail;

FIG. 3 is a diagram illustrating an operating status of the memory device of FIG. 1;

FIG. 4A is a timing chart illustrating an operation timing of a general memory device;

FIG. 4B is a timing chart illustrating a parallel operation timing of a subbank level;

FIG. 4C is a timing chart illustrating an operation timing of the memory device of FIG. 1;

FIG. 5A is a timing chart illustrating an ACT command for a second subbank in a status when a first subbank is activated;

FIG. 5B is a timing chart illustrating an ACT command for the second subbank in a status when the first subbank is deactivated;

FIG. 6 is a block diagram illustrating a memory device according to another embodiment;

FIG. 7 is a block diagram illustrating a memory system according to an embodiment;

FIG. 8 is a block diagram illustrating the memory controller of FIG. 7 in detail;

FIGS. 9A and 9B are flowcharts illustrating respective operating methods of the memory system of FIG. 7;

FIG. 10 is a diagram illustrating a memory module which includes a memory device according to some example embodiments;

FIG. 11 is a block diagram illustrating an exemplary computer system which includes a memory device according to some example embodiments; and

FIG. 12 is a block diagram illustrating an exemplary system on chip which includes a memory device according to some example embodiments.

### DETAILED DESCRIPTION OF THE EMBODIMENTS

The example embodiments will now be described more fully hereinafter with reference to the accompanying drawings, in which example embodiments are shown. This example embodiments may, however, be embodied in different forms and should not be construed as limited to those set forth herein. Rather, these embodiments are provided so that this disclosure will be thorough and complete, and will fully convey the scope of the inventive concepts to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

The example embodiments will be described with reference to perspective views, cross-sectional views. Thus, the profile of an example view may be modified according to manufacturing techniques and/or allowances. That is, the embodiments are not intended to limit the scope of the inventive concepts but cover all changes and modifications that can be caused due to a change in manufacturing process. Thus, regions shown in the drawings are illustrated in schematic form and the shapes of the regions are presented simply by way of illustration and not as a limitation.

As a memory process is miniaturized, the number of timing parameters of the memory device is increased. The timing parameters of the memory device include a write latency time tWL, a write recovery time tWR, a row precharge time tRP, and a row to column delay time tRCD. Among these timing parameters, as the write recovery time tWR is increased, a write operating time of the memory device may be increased. In order to recover performance loss caused by the increase of the timing parameters, a parallel operation of the subbank level is suggested.

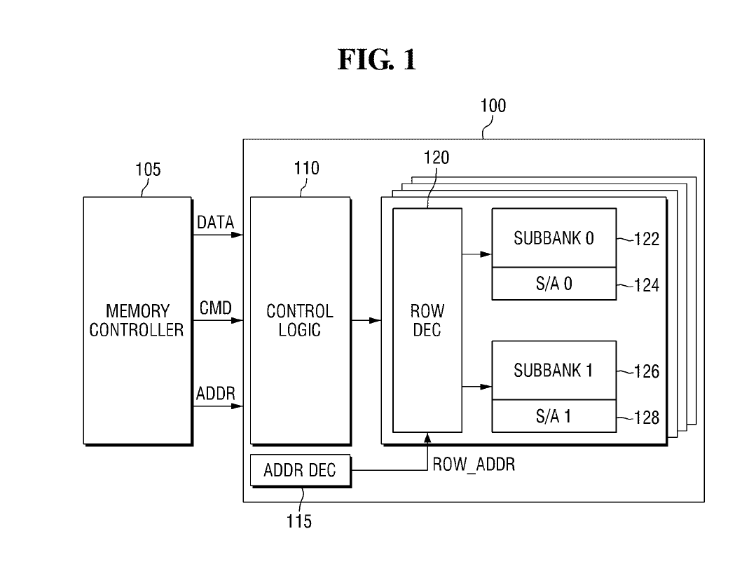

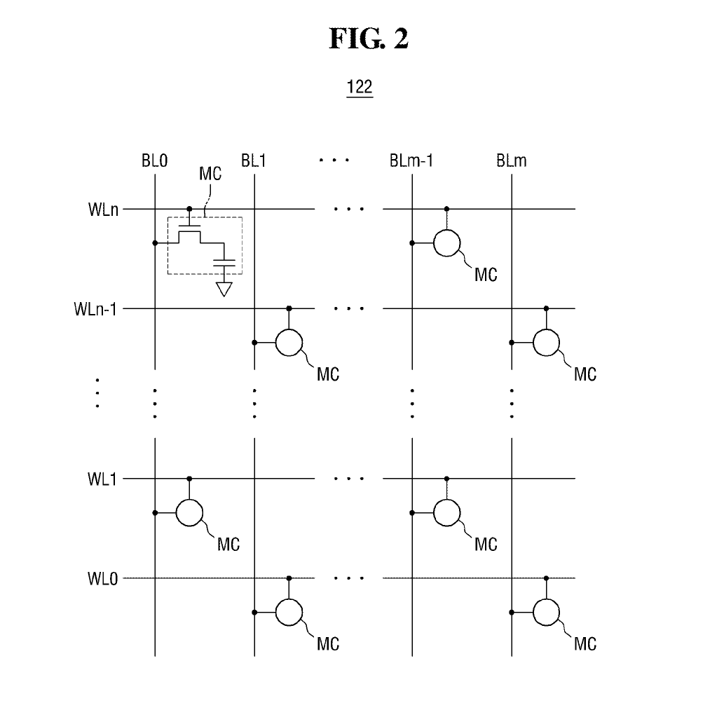

FIG. 1 is a block diagram illustrating a memory controller and a memory device according to an example embodiment, and FIG. 2 is a circuit diagram illustrating subbanks of FIG. 1 in detail.

Referring to FIG. 1, a memory device 100 according to an example embodiment includes a control logic 110, address decoder 115, and a plurality of memory banks 120.

In FIG. 1, the memory device 100 includes four memory banks 120 but the example embodiments are not limited thereto and the number of memory banks 120 may vary.

Each memory bank 120 may include a row decoder (ROW DEC) 121, first and second subbanks (SUBBANK 0 and SUBBANK 1) 122 and 126, and first and second sense amplifiers (S/A 0 and S/A 1) 124 and 128.

The row decoder 121 may activate a row of one subbank, which is selected from the first and second subbanks 122 and 126. Hereinafter, stating that “the subbank is activated” may also mean that “the row of the subbank is activated”. The row decoder 121 may receive a row address ROW_ADDR from the address decoder 115 (or, address register), which generates a column address and the row address ROW_ADDR from an address ADDR received from the memory controller. The row decoder 121 may activate a row of a subbank corresponding to the row address. Here, stating that the row of the subbank is activated indicates that a write voltage is supplied to the row of the subbank. Alternatively, stating that the row of the subbank is activated may indicate that the row of the subbank is open.

Even though it is not illustrated, the row decoder 121 may receive a bank address BANK_ADDR from address decoder 115 or other element (for example, a bank control logic (not illustrated)). The row decoder 121 may select a memory bank corresponding to a bank address from a plurality of memory banks 120. That is, the row decoder 121 may activate a row of one selected subbank of the selected memory bank.

Each of the first and second subbanks 122 and 126 may include a plurality of memory cells to store data, for example, supplied by the memory controller 105. For example, the first and second subbanks 122 and 126 may be arranged in a row direction, but the example embodiments are not limited thereto. The first subbank 122 may be connected to the row decoder 121 and the first sense amplifier 124; and the second subbank 126 may be connected to the row decoder 121 and the second sense amplifier 128.

The first and second subbanks 122 and 126 may be a set of memory cells which share the first and second sense amplifiers 124 and 128 in the memory bank 120. For example, each of the first and second subbanks 122 and 126 may correspond to at least one page, but the example embodiments are not limited thereto.

Referring to FIG. 2, the first subbank 122 may include a plurality of word lines WL0 to WLn, a plurality of bit lines BL0 to BLm, and a plurality of memory cells MCs.

The plurality of memory cells MCs may be arranged at intersections of the plurality of word lines WL0 to WLn and the plurality of bit lines BL0 to BLm. Each memory cell MC may have a dynamic random access memory (DRAM) cell structure. For example, each memory cell MC may include a switching transistor and an information storing capacitor. A gate of the switching transistor may be connected to the word line and a source/drain of the switching transistor may be connected to the bit line/information storing capacitor. Each memory cell MC may store data corresponding to a quantity of electric charge, which is stored in the information storing capacitor.

The word lines WL0 to WLn, which are connected to the memory cells MCs, may be defined as rows of the first subbank 122; and the bit lines BL0 to BLm, which are connected to the memory cells MCs, may be defined as columns of the first subbank 122.

Even though it is not illustrated, the second subbank 126 may have the same structure as the first subbank 122, which has been described with reference to FIG. 2.

Referring to FIG. 1 again, the first and second sense amplifiers 124 and 128 may precharge the first and second subbanks 122 and 126, respectively. Here, the precharging of the subbank indicates that a precharge voltage is supplied to the column of the subbank. Alternatively, the precharging of the subbank may indicate that the row of the subbank is closed. The first and second sense amplifiers 124 and 128 may read out data from the first and second subbanks 122 and 126, respectively.

The plurality of memory banks 120 may independently operate. That is, parallel operation at the memory bank level may be allowed. Each of the memory banks 120 includes a respective row decoder 121 so that one memory bank and another memory bank may be simultaneously activated. Further, each of the memory banks 120 includes a respective set of the sense amplifiers 122 and 126 so that one memory bank and another memory bank may be simultaneously precharged.

The control logic 110 may control operations of the memory device 100. The control logic 110 may receive a command CMD from the memory controller 105. The control logic 110 may control the row decoder 121, the first and second sense amplifiers 124 and 128 in response to the command.

The command may include an ACT command and a PRE command. Here, the ACT command is a command for activating the row of the selected memory bank 120. The memory bank 120 includes one row decoder 121 so that a row of one subbank selected from the plurality of subbanks 122 and 126 may be activated. The PRE command is a command for precharging and deactivating the activated memory bank 120. The memory bank 120 includes the plurality of sense amplifiers 124 and 128 so that the plurality of subbanks 122 and 126 may be individually precharged.

The control logic 110 controls the row decoder 121 in response to the ACT command to activate a row of one subbank selected from the first and second subbanks 122 and 126. The control logic 110 controls one of the first and second sense amplifiers 124 and 128 in response to the PRE command to precharge a corresponding subbank.

For example, the row decoder 121 may activate the row of the first subbank 122 in response to the ACT command for activating the row of the first subbank 122. Alternatively, the row decoder 121 may activate the row of the second subbank 126 in response to the ACT command for activating the row of the second subbank 126.

Further, in the memory device 100 according to an example embodiment if or when the row of the second subbank 126 is activated, the second sense amplifier 128 may automatically precharge the second subbank 126 in response to the ACT command for activating the row of the first subbank 122. Alternatively, if or when the row of the first subbank 122 is activated, the first sense amplifier 124 may automatically precharge the first subbank 122 in response to the ACT command for activating the row of the second subbank 126.

The control logic 110 may store and manage the active status of the first and second subbanks 122 and 126. The active status of the subbanks may be managed for every memory bank 120. When an ACT command for activating a row of any one of the subbanks is received, the control logic 110 may determine whether a row of another subbank is activated. In accordance with the determination result, the control logic 110 controls the memory device 100 to precharge or not to precharge another subbank.

In accordance with embodiments, the ACT command, which is transferred from the memory controller 105, may be divided into a plurality of types based on whether to accompany a precharge instruction. In this case, the ACT command may include a first ACT command, which accompanies a precharge instruction for another subbank, and a second ACT command, which does not accompany the precharge instruction for another subbank. The memory device 100 may distinguish the first ACT command and the second ACT command for any one of the subbanks to precharge or not to precharge another subbank. For example, the second sense amplifier 128 precharges the second subbank 126 in response to the first ACT command for activating the row of the first subbank 122, but does not precharge the second subbank 126 in response to the second ACT command for activating the row of the first subbank 122. The second sense amplifier 128 may operate in the same respective manner for the case of the first and second ACT commands for activating the row of the second subbank 126. The first ACT command may be referred to as a toggling ACT command.

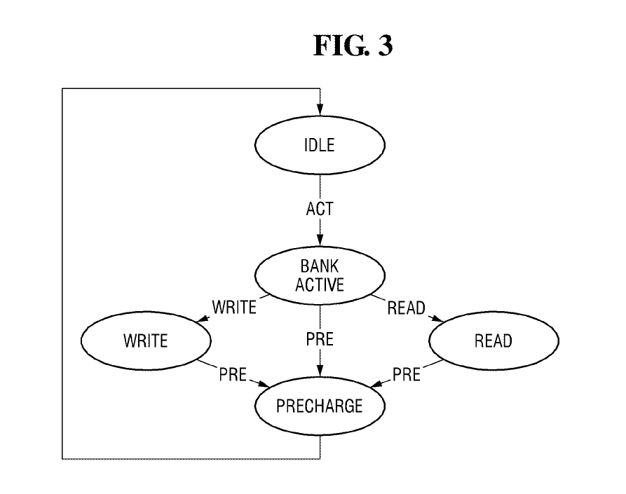

FIG. 3 is a diagram illustrating an operating status of the memory device of FIG. 1.

Referring to FIG. 3, the operating status of the memory device 100 may include an idle status IDLE, a bank active status BANK ACTIVE, a writing status WRITE, a reading status READ, and a precharge status PRECHARGE.

When a power is supplied, the memory device 100 may enter the idle status IDLE or the precharge status PRECHARGE. When a precharge operation is completed, the memory device 100 may enter the idle status IDLE from the precharge status PRECHARGE.

When the memory device 100 receives the ACT command, the memory device 100 may enter the bank active status BANK ACTIVE from the idle status IDLE.

When the memory device 100 receives the WRITE command or the READ command, the memory device 100 may enter the writing status WRITE or the reading status READ from the bank active status BANK ACTIVE. Next, when the memory device 100 receives the PRE command, the memory device 100 may enter the precharge status PRECHARGE from the writing status WRITE or the reading status READ.

In the meantime, when the memory device 100 receives the PRE command, the memory device 100 may directly enter the precharge status PRECHARGE from the bank active status BANK ACTIVE.

As described above, the plurality of memory banks 120 may independently operate so that the bank active status BANK ACTIVE may be allocated into individual memory banks 120. Alternatively, as described below, when parallel operation at the subbank level is available, the active status may be allocated for more than one (or all) subbank of each memory bank 120.

Even though it is not specifically illustrated, the operating status of the memory device 100 may further include a status, which is well known in the art, such as a self refresh status SELF REFRESH, an auto refresh status AUTO REFRESH, a suspend status SUSPEND, a power on status POWER ON, or a power down status POWER DOWN in addition to the statuses described with reference to FIG. 3.

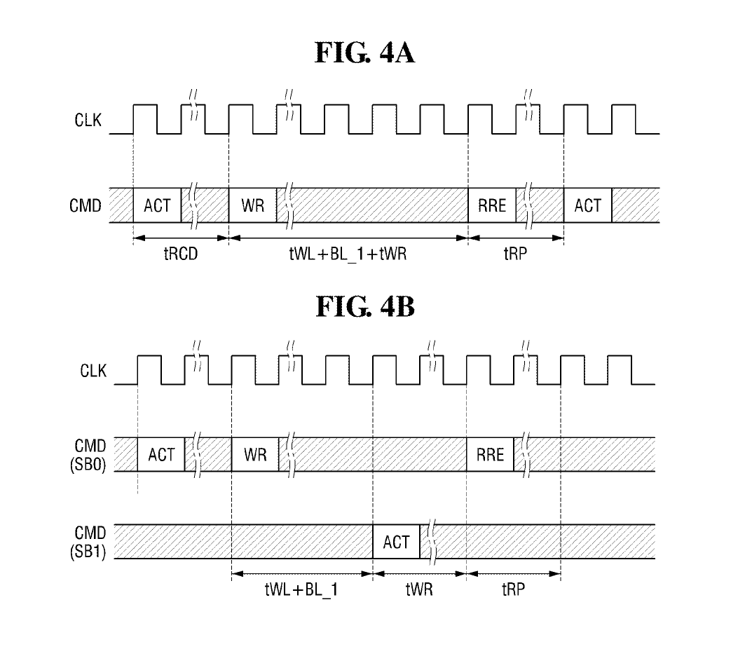

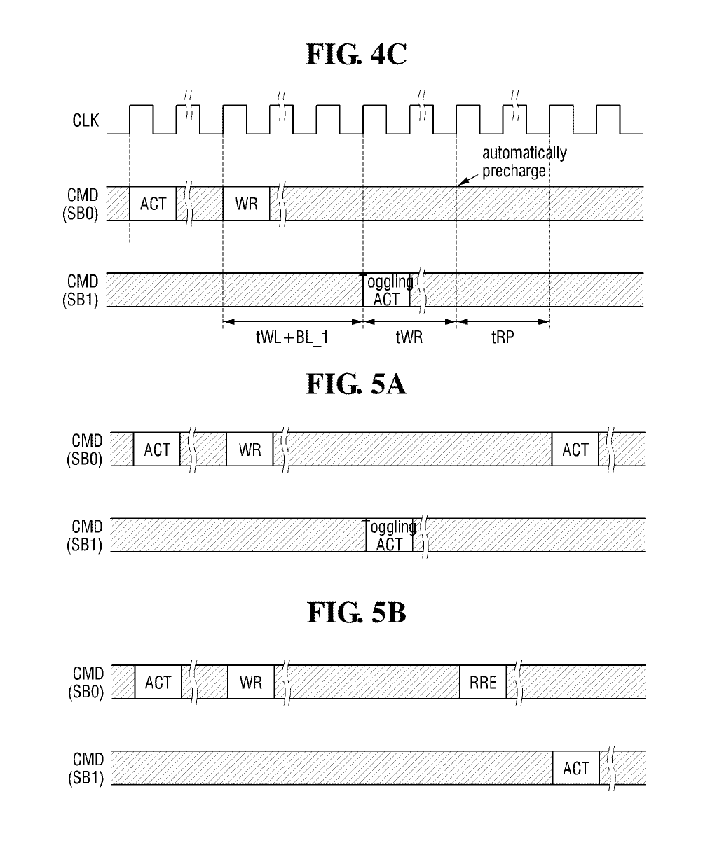

FIG. 4A is a timing chart illustrating an operation timing of a general memory device.

FIG. 4B is a timing chart illustrating a parallel operation timing of a sub bank level.

FIG. 4C is a timing chart illustrating an operation timing of the memory device of FIG. 1.

In FIGS. 4A to 4C, each command is defined at a rising edge of the clock CLK but the example embodiments are not limited thereto, and each command may be defined at a falling edge of the clock.

In FIGS. 4B and 4C, reference numerals “SB0” and “SB1” are used to distinguish a command related to the first subbank 122 and a command related to the second subbank 126 and it will be obvious to those skilled in the art that the commands are provided through the same command bus to the control logic 110.

Referring to FIG. 4A, a WRITE command for the memory bank is issued at a time of a tRCD after issuing the ACT command for any one of the memory banks. As the ACT command is issued, the row of the memory bank is activated and as the WRITE command is issued, a writing operation on the memory cells, which are disposed in the row of the memory bank, is performed. The writing operation of the memory bank may be performed during the time of tWL+BL−1+tWR. Here, “BL” may indicate a burst length and “1” may indicate one clock cycle. After performing the wiring operation, a PRE command for the memory bank is issued. As the PRE command is issued, a precharge operation for the memory bank is performed so that the memory bank is deactivated. The precharge operation of the memory bank may be performed during the time of tRP. Thereafter, an ACT command for another memory bank may be issued or an ACT command for the same memory bank may be issued.

Referring to FIG. 4B, an ACT command for the first subbank 122 of any one of the memory banks is issued to the control logic 110 and then a command for the first subbank 122 is issued to the control logic 110 after the time of tRCD from the issuance of the ACT command. The writing operation of the subbank may be performed during the time of tWL+BL−1+tWR, as described above. After performing the writing operation, a PRE command for the first subbank 122 is issued to the control logic 110. The precharge operation of the subbank may be performed during the time of tRP, as described above.

In the meantime, when parallel operation of the memory device at the subbank level is performed, an ACT command for the second subbank 126 may be issued at the time of tWR of the writing operation of the first subbank 122. That is, the ACT command for the second subbank 126 may be provided to the control logic 110 at the time of tWL+BL−1 after supplying the WRITE command.

As described above, when parallel operation of the memory device at the subbank level is performed, activating operations of a plurality of subbanks may overlap at a writing operation time (or a reading operation time). Therefore, the increase of the time of tWR may be hidden to the memory controller.

However, in order to perform the parallel operation in the subbank level, the number of ACT commands and PRE commands which need to be issued by the memory controller may be disadvantageously increased. Further, the memory controller needs to consider a complex timing parameter between the PRE command for the first subbank 122 and the ACT command for the second subbank 126. Further, the memory controller needs to store the active status for every subbank which configures the memory bank, which may increase the logic region of the memory controller.

Referring to FIG. 4C, in the memory device 100 of FIG. 1, a toggling ACT command for the second subbank 126 may be provided by the memory controller 105 at the time of tWR of the writing operation of the first subbank 122. The toggling ACT command is a command obtained by combining the ACT command for any one of the subbanks with the PRE command for another subbank as described above. Here, the control logic 110 is configured to recognize and implement the toggling ACT command. In this example, because the toggling ACT command for the second subbank 126 is provided, the row of the second subbank 126 is activated. When the time of tWR has elapsed after supplying the toggling ACT command (or when the time of tWL+BL−1+tWR has elapsed after supplying the WRITE command), the precharge operation for the first subbank 122 is automatically performed to deactivate the first subbank 122.

Accordingly, according to the memory device of FIG. 1, the memory controller 105 does not need to separately issue the PRE command for the first subbank 122. Therefore, the memory controller 105 may not consider the complex timing parameter between the PRE command for the first subbank 122 and the ACT command for the second subbank 126. Further, the memory controller 105 does not need to separately issue the PRE command, and a bandwidth of a command bus is not increased. Further, the memory controller 105 does not store the active status for every subbank of the memory bank, but stores an active status which indicates whether there is an open subbank for every memory bank.

While 4C and the discussion above provided one example where the first subbank was automatically precharged, it will be appreciated that the situation may be reversed, and the second subbank will be automatically precharged.

FIG. 5A is a timing chart illustrating an ACT command for a second sub bank in a status when a first sub bank is activated and

FIG. 5B is a timing chart illustrating an ACT command for the second sub bank in a status when the first sub bank is non-activated.

Referring to FIG. 5A, as the ACT command for the first subbank 122 is issued, the row of the first subbank 122 may be activated. Thereafter, as the ACT command for the second subbank 126 is issued, the row of the second subbank 126 may be activated. Thereafter, the ACT command for the first subbank 122 is reissued, the row of the first subbank 122 may be activated. Here, the PRE command for the first subbank 122 is not issued between the ACT command for the first subbank 122 and the ACT command for the second subbank 126. Further, the PRE command for the first subbank 122 is not issued between the ACT command for the second subbank 126 and the ACT command, which is reissued for the first subbank 122. This is because the first subbank 122 is precharged in response to the toggling ACT command for the second subbank 126.

Referring to FIG. 5B, as the ACT command for the first subbank 122 is issued, the row of the first subbank 122 may be activated. Thereafter, as the PRE command for the first subbank 122 is issued, and subsequently the row of the first subbank 122 may be deactivated. Thereafter, the ACT command for the second subbank 126 is issued, and thus the row of the second subbank 126 may be activated. Here, the ACT command for the second subbank 126 is a general ACT command so that the first subbank 122 is not precharged in response to the ACT command for the second subbank 126.

The memory controller 105 stores the active statuses of the first and second subbanks 122 and 126 for every memory bank so that if there is a currently activated subbank, the memory controller may issue a toggling ACT command, which accompanies a PRE command for the currently activated subbank. If there is no currently activated subbank, the memory controller may issue the general ACT command, which does not accompany the PRE command.

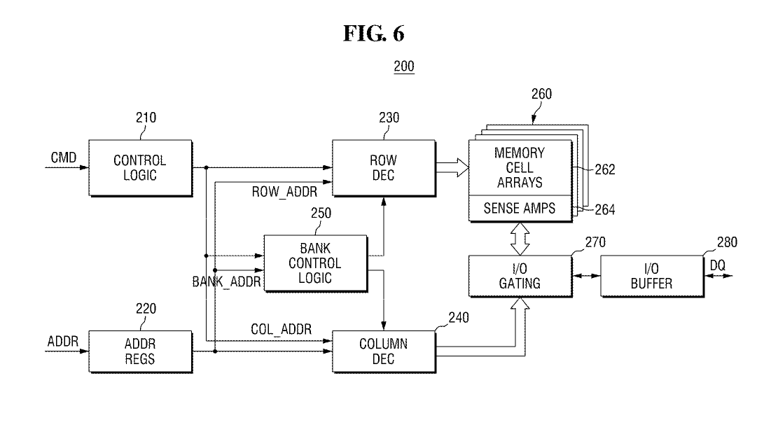

FIG. 6 is a block diagram illustrating a memory device according to another embodiment.

Referring to FIG. 6, a memory device 200 includes a control logic (CONTROL LOGIC) 210, an address register (ADDRESS REGS) 220, a row decoder (ROW DEC) 230, a column decoder (COLUMN DEC) 240, a hank control logic (BANK CONTROL LOGIC) 250, a memory cell array 260, an input/output gating circuit (I/O GATING) 270, and an input/output buffer (I/O BUFFER) 280. Here, the memory controller supplying the command CMD and address ADDR is not shown.

The control logic 210 may control an operation of the memory device 200 by receiving a command CMD from the memory controller (not illustrated). For example, the control logic 210 may generate control signals by decoding the command CMD including a write enable signal /WE, a row address strobe signal /RAS, a column address strobe signal /CAS, or a chip selection signal /CS. The control logic 210 may provide the control signals to the row decoder 230, the column decoder 240, and the bank control logic 250 so that the memory device 200 performs a writing, reading, or erasing operation. In accordance with an example embodiment, the control logic 210 may store the active status of the subbanks for every memory bank 262 of the memory cell array 260 and control the precharge operation of the memory device 200.

The address register 220 may receive an address ADDR from the memory controller. For example, the address register 220 may receive the address ADDR including a row address signal ROW_ADDR and a column address signal COL_ADDR. Further, the address register 220 may also receive a bank address signal BANK_ADDR. The address register 220 may provide the received row address signal ROW_ADDR to the row decoder 230, provide the received column address signal COL_ADDR to the column decoder 240, and provide the received bank address signal BANK_ADDR to the bank control logic 250.

The row decoder 230 may activate the row of the memory bank 260 corresponding to the row address signal ROW_ADDR. The column decoder 240 may activate the sense amplifier 264 corresponding to the column address signal COL_ADDR through the input/output gating circuit 270. A plurality of row decoders 230 and a plurality of column decoders 240 respectively corresponding to the plurality of memory banks 262.

The bank control logic 250 may generate bank control signals in accordance with the bank address signal BABK_ADDR. The bank control logic 250 may provide the bank control signals so as to operate the row decoder 230 and the column decoder 240 corresponding to the bank address signal BANK_ADDR.

The memory cell array 260 may include the plurality of memory banks 262.

Each memory bank 262 may include a plurality of memory cells for storing data. Each memory bank 262 may include a plurality of word lines and a plurality of bit lines, and the plurality of memory cells may be disposed at the intersections of the plurality of word lines and the plurality of bit lines. Each memory cell may have a dynamic random access memory (DRAM) cell structure. The plurality of memory cells may configure a plurality of subbanks.

A plurality of sense amplifiers 264 may be connected to the plurality of memory banks 262, respectively. Each sense amplifier 264 may precharge a corresponding subbank as described with reference to FIG. 1.

The input/output gating circuit 270 may include write drivers for writing data in the memory cell array 260 and reading latches for storing the data read from the memory cell array 260, together with circuits which gate input/output data.

The input/output buffer 280 may receive data DQ to be written in the memory cell array 260 from the memory controller. The input/output buffer 280 may provide the data DQ to be written in the memory cell array 260 to the memory cell array 260 through the writing drivers. The data DQ read from the memory cell array 260 may be detected by the sense amplifier 264 and stored in the reading latches. The input/output buffer 280 may provide the data DQ stored in the reading latches to the memory controller.

The memory device 200 of FIG. 6 may operate in the same manner to the memory device 100 which has been described with reference to FIG. 1.

In FIG. 6, the row decoder 230 is configured separately from the memory cell array 260, but the example embodiments are not limited thereto and the row decoder 230 may be configured to be included in the memory bank 262 of the memory cell array 260. Even though it is not illustrated, the memory device 200 may further include non-illustrated other constituent elements.

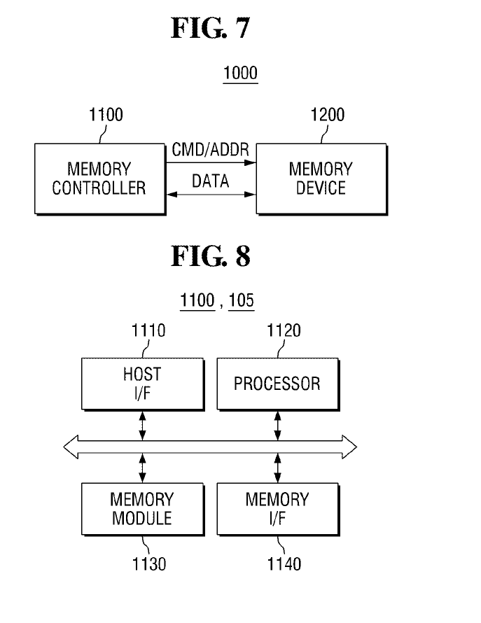

FIG. 7 is a block diagram illustrating a memory system according to an embodiment.

The memory system 1000 includes a memory controller 1100 and a memory device 1200.

The memory controller 1100 may be configured to control the memory device 1200. The memory controller 1100 may provide a command CMD and an address ADDR to the memory device 1200 and exchange data DATA with the memory device 1200. For example, the memory controller 1100 may issue an ACT command and a PRE command, but the example embodiments are not limited thereto.

As described with reference to FIG. 1, the memory controller 1100 may issue a first ACT command which accompanies a precharge command for another subbank and a second ACT command which does not accompany the precharge command for another subbank. The memory controller 1100 may issue other commands which are well known in the art such as an REF command, a CKE command, a WRITE command, a READ command, or an MRS command.

The memory device 1200 may be configured to store data. The memory device 1200 may be the memory device 100, which has been described with reference to FIG. 1, or the memory device 200, which has been described with reference to FIG. 6. And, the memory controller 1100 may be the same memory controller of those embodiments.

FIG. 8 is a block diagram illustrating the memory controller of FIG. 7 or FIG. 1 in detail.

Referring to FIG. 8, the memory controller includes a host interface (HOST I/F) 1110, a processor (PROCESSOR) 1120, a memory module (MEMORY MODULE) 1130, and a memory interface (MEMORY I/F) 1140 as sub components.

The host interface 1110 may be configured to interface with a host.

The processor 1120 may be configured to control all operations of the memory controller 1100.

The memory module 1130 may be used as at least one of an operation memory of the processor 1120, and a cache memory or a buffer memory between the host and the memory device 1200. For example, the memory module 1130 may be a static RAM (SRAM), but the example embodiments are not limited thereto. The memory module 1130 may store the active status of the memory bank.

The memory interface 1140 may be configured to interface with the memory device 1200. For example, the memory interface 1140 may provide the command CMD and the address ADDR to the memory device 1200, and exchange the data DQ with the memory device 1200.

Even though it is not illustrated, the memory controller may further include non-illustrated other constituent elements.

The memory controller may issue the first ACT command or the second ACT command with reference to the active status of the memory bank. For example, when the memory controller 1100 activates the row of the first subbank, if the second subbank is activated, the memory controller 1100 issues the first toggling ACT command. If the second subbank is deactivated, the memory controller 1100 may issue the second ACT command.

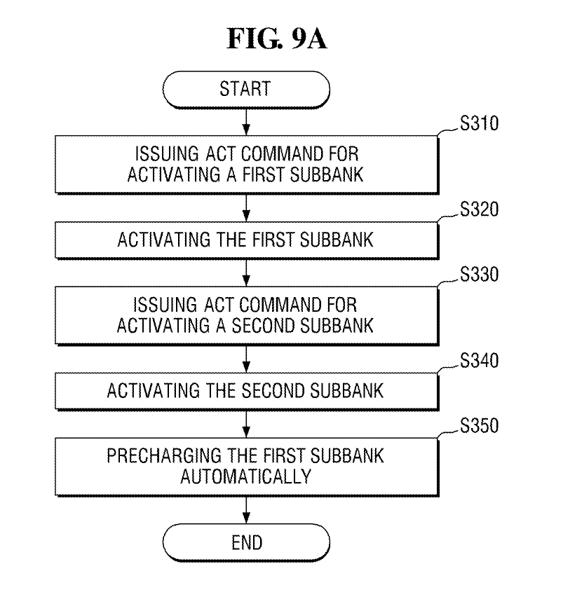

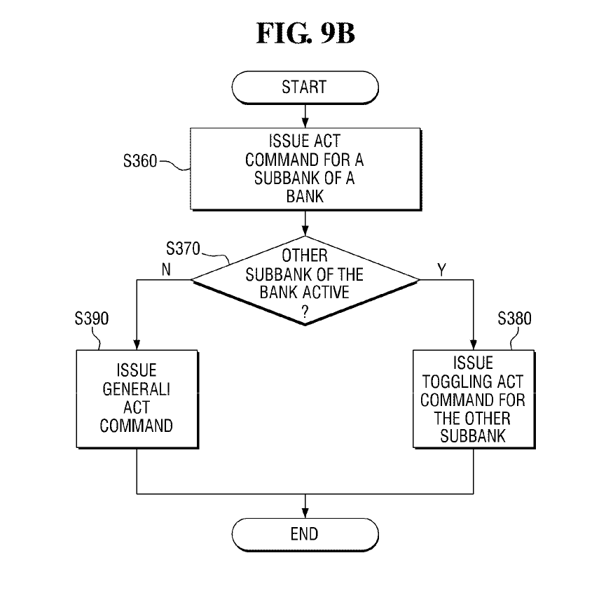

FIG. 9A is a flowchart illustrating an operating method of the memory system of FIG. 7.

Referring to FIG. 9A, in step S310, the memory controller 1100 issues an ACT command for activating the row of the first subbank of the memory bank of the memory device 1200.

Next, in step S320, the row decoder of the memory device 1200 activates the row of the first subbank in response to the ACT command.

Next, in step S330, the memory controller 1100 issues an ACT command for activating the row of the second subbank which is different from the first subbank of the memory bank.

Next, in step S340, the row decoder of the memory device 1200 activates the row of the second subbank in response to the ACT command and then in step S350, the first sense amplifier of the memory device 1200 automatically precharges the first subbank.

The first and second subbanks may be a set of memory cells which share one sense amplifier in the memory bank. In other words, the first subbanks may share the first sense amplifier and the second subbanks may share the second sense amplifier. Each of the first and second subbanks may correspond to at least one page, but the present invention is not limited thereto.

FIG. 9B illustrates a flow chart of an operating method of the memory system of FIG. 7 according to another embodiment.

As shown in step S360 of FIG. 9B, the processor 1120 of the memory controller 1100 issues an ACT command for a subbank (e.g., first subbank) of a bank in the memory device 1200. When the processor 1120 wants to activate another subbank (e.g., second subbank) of the bank, the processor 1120 checks the memory module 1130 to determine if the other (e.g., first subbank) is active in step S370. If so, then in step S380, the processor 1120 issues the first or toggling ACT command for the, for example, second subbank. Otherwise, in step S390, the processor 1120 issues the second or general ACT command.

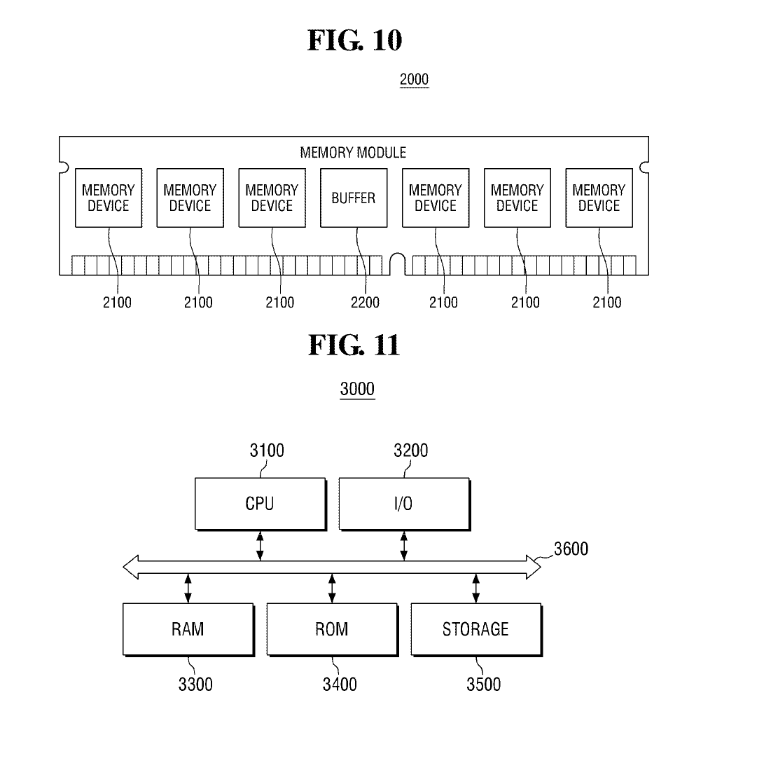

FIG. 10 is a diagram illustrating a memory module which includes a memory device according to some example embodiments.

Referring to FIG. 10, a memory module 2000 includes a plurality of memory devices 2100.

The memory module 2000 may further include a buffer 2200, which receives a command CMD, an address ADDR, data DQ from the memory controller, and buffers the command CMD, the address ADDR, and the data DQ to provide the command CMD, the address ADDR, and the data DQ to the memory devices 2100.

Data DQ transmission lines between the buffer 2200 and the memory devices 2100 may be connected in a point-to-point manner. Further, command CMD/address ADDR transmission lines between the buffer 2200 and the memory devices 2100 may be connected in a multi-drop manner, a daisy-chain manner, or a fly-by daisy-chain manner.

The buffer 2200 buffers the command CMD, the address ADDR, and the data DQ so that memory controller may drive only a load of the buffer 2200 to interface with the memory module 2100.

The plurality of memory devices 200 may be the memory device 100, which has been described with reference to FIG. 1 or the memory device 200, which has been described with reference to FIG. 6.

The memory module 2000 may be an arbitrary memory module such as a unbuffered dual in-line memory module (UDIMM), a registered dual in-line memory module (RDIMM), a fully buffered dual in-line memory module (FBDIMM), or a load reduced dual in-line memory module (LRDIMM).

FIG. 11 is a block diagram illustrating an exemplary computer system which includes a memory device according to some example embodiments.

Referring to FIG. 11, a computer system 3000 includes a central processing unit (CPU) 3100, an input/output device (I/O) 3200, a RAM 3300, a ROM 3400, a storage device (STORAGE) 3500, and a data bus 3600.

The CPU 3100, the input/output device 3200, the RAM 3300, the ROM 3400, and the storage device 3500 may be coupled to each other through the data bus 3600. The data bus 3600 corresponds to a path through which data move.

The CPU 3100 may include a controller and an operating device to execute a program and process data. The CPU 3100 may also include a cache memory located inside or outside.

The input/output device 3200 may include at least one input device, which includes a mouse and a keyboard to input data, and at least one output device, which includes a monitor, a speaker, or a printer to output data.

The RAM 3300 and the ROM 3400 may transmit and receive data to and from the CPU 3100 and store data and/or command languages required to execute the program. The RAM 3300 is a volatile memory device and the ROM 3400 is a nonvolatile memory device. The RAM 3300 may be the memory device 100, which has been described with reference to FIG. 1, or the memory device 200, which has been described with reference to FIG. 6.

The storage device 3500 may include a nonvolatile storage device such as a floppy disk, a hard disk, a CD-ROM, or a DVD to store data and/or a command language.

Even though it is not illustrated, the computer system 3000 may further include an interface device, which transmits data to a communication network or receives data from the communication network. The interface device may be a wired or wireless type. For example, the interface device may include an antenna or a wired or wireless transceiver.

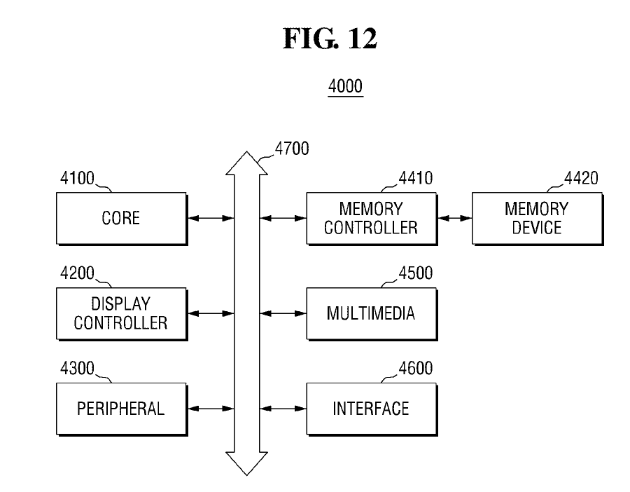

FIG. 12 is a block diagram illustrating an exemplary system on chip which includes a memory device according to some example embodiments.

Referring to FIG. 12, a system on chip 4000 may be configured to include a core device (CORE) 4100, a display controller (DISPLAY CONTROLLER) 4200, a peripheral device (PERIPHERAL) 4300, a memory controller (MEMORY CONTROLLER) 4410, a memory device (MEMORY DEVICE) 4420, a multimedia device (MULTIMEDIA) 4500, an interface device (INTERFACE) 4600, and a data bus 4700.

The core device 4100, the display controller 4200, the peripheral device 4300, the memory controller 1110, the memory device 4420, the multimedia device 4500, and the interface device 4600 may be coupled to each other through the data bus 4700. The data bus 4700 corresponds to a path through which data moves.

The core device 4100 may include a single process core (single core), or a plurality of process cores (multi-core) to process data. For example, the core device 4100 may include a multi-core, such as a dual-core, a quad-core, and a hexa-core.

The display controller 4200 controls a display device to display an image or a video.

The peripheral device 4300 may include device such as a serial communication device, a memory management device, or an audio processing device.

The memory controller 4410 is configured to control the memory device 4420. The memory controller 4410 may provide a command/address to the memory device 4420 and exchange data with the memory device 4420. The memory controller 4410 may issue a first ACT command, which accompanies a precharge instruction for another subbank, and a second ACT command, which does not accompany the precharge instruction for another subbank.

The memory device 4420 may be configured to store data. The memory device 4420 may include at least one of volatile memory devices such as a double data rate static DRAM (DDR SDRAM), a single data rate SDRAM (SDR SDRAM), or a static random access memory (SRAM) and/or at least one of nonvolatile memory devices such as an electrical erasable programmable ROM (EEPROM) or a flash memory. The volatile memory device may be the memory device 100, which has been described with reference to FIG. 1, or the memory device 200, which has been described with reference to FIG. 6.

The multimedia device 4500 may include a two-dimensional/three-dimensional graphic engine, an image signal processor (ISP), and a codec engine to process a multimedia operation.

The interface device 4600 may perform a function to transmit data to a communication network or receive data from the communication network.

In concluding the detailed description, those skilled in the art will appreciate that many variations and modifications can be made to the example embodiments without substantially departing from the principles of the inventive concepts. Therefore, the disclosed example embodiments of the inventive concepts are used in a generic and descriptive sense only and not for purposes of limitation.

1. A memory device, comprising:
at least one memory bank including first and second subbanks; and
a control logic configured to control storing data into the memory bank, the control logic configured to activate the first subbank and to precharge the second subbank in response to a first activate command for the first subbank.

2. The memory device of claim 1, wherein the control logic is configured to active the first subbank and not precharge the second subbank in response to a second activate command for the first subbank.

3. The memory device of claim 1, wherein the control logic is configured to control a sense amplifier to precharge the second subbank.

4. The memory deivce of claim 3, wherein the sense amplifier is configured to precharge the second subbank in response to a PRE command.

5. The memory device of claim 4, wherein the sense amplifier is configured to precharge the second subbank in response to an ACT command for activating the first subbank.

6. The memory device of claim 5, wherein the ACT command is one of a first ACT command and a second ACT command, and the sense amplifier precharges the second subbank in response to the first ACT command and does not precharge the second subbank in response to the second ACT command.

7. The memory device of claim 5, wherein when the second subbank is in the active status, the sense amplifier is configured to precharge the second subbank in response to the ACT command for activating the first subbank; and
when the second subbank is in a deactive status, the sense amplifier is configured to not precharge the second subbank in response to the ACT command for activating the first subbank.

8. The memory device of claim 3, wherein the first and second subbanks each include memory cells which share the sense amplifier.

9. The memory device of claim 1, wherein the first and second subbanks correspond to at least one page, respectively.

10. A memory controller comprising:
a processor configured to issue a first activate command to activate a first subbank in a bank of a memory device if a second subbank of the bank is active, the first activate command instructing the memory device to activate the first subbank and to precharge the second subbank.

11. The memory controller of claim 10, further comprising:
a memory configured to store a respective status for each of the first and second subbanks, the status indicating whether the respective one of the first and second subbanks is active; and wherein
the processor is configured to generate the first activate command based on the statuses.

12. The memory controller of claim 10, wherein the processor is configured to generate a second activate command to activate the first subbank if the second subbank is inactive, the second activate command instructing the memory device to activate the first subbank.

13. A system on chip comprising:
a memory device configured to store data; and
a memory controller configured to control the memory device, the memory device including,
at least one memory bank including a plurality of subbanks;
a row decoder configured to activate a row of one subbank which is selected from the plurality of subbanks; and
a plurality of sense amplifiers configured to precharge the plurality of subbanks, respectively, and wherein
the memory controller is configured to issue an ACT command for activating a row of one subbank which is selected from the plurality of subbanks, and after issuing the ACT command, the memory controller is configured to not issue a PRE command but reissue an ACT command for activating the row of the one selected subbank.

14. The system on chip of claim 13, wherein after issuing the ACT command for activating the row of the one selected subbank and before reissuing the ACT command for activating the row of the one selected subbank, the memory controller is configured to issue an ACT command for activating a row of another subbank which is selected from the plurality of subbanks.

15. The system on chip of claim 14, wherein one sense amplifier of the plurality of sense amplifiers is configured to precharge the one selected subbank in response to the ACT command for activating the row of another selected subbank.

16. The system on chip of claim 15, wherein after the row decoder activates the row of another selected subbank, one sense amplifier of the plurality of sense amplifiers is configured to precharge the one selected subbank in response to the ACT command for activating the row of another selected subbank.

17. The system on chip of claim 13, wherein the plurality of subbanks each include memory cells which share the plurality of sense amplifiers in at least one memory bank.

18. The system on chip of claim 17, wherein the plurality of subbanks corresponds to at least one page, respectively.

19-39. (canceled)
